(19) United States
(12) Patent Application Publication
(10) Pub. No.: US 2008/0050982 A1
(43) Pub. Date: Feb. 28, 2008

(54) ELECTRONIC MODULE AND METHOD OF MANUFACTURING ELECTRONIC MODULE

(75) Inventor: Kumiko Kaneko, Yokohama-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/843,887

(22) Filed: Aug. 23, 2007

(30) Foreign Application Priority Data
Aug. 25, 2006 (JP) 2006-228754
Aug. 3, 2007 (JP) 2007-202724

(51) Int. Cl. H01R 9/22; G01R 31/28

(52) U.S. Cl. 439/721; 29/593

(57) ABSTRACT

An electronic module capable of easily determining connection reliability of an ACF connection portion is provided. Electrode wirings of a board serving as an electronic parts of a display panel are connected with ACF bonding wirings of an FPC through an ACF to make electrical connection between the FPC and the board. Two branch portions branched from each of the ACF bonding wirings extend to an edge of the FPC. Low resistance measurement of the connection portion can be performed using the electrode wiring of the board and the branch portions, so whether or not the ACF connection portion is faulty can be determined.

### BACKGROUND OF THE INVENTION

1. Field of the Invention

The present invention relates to an electronic module including electronic parts and a method of manufacturing the electronic module.

2. Description of the Related Art

Electronics industry has made significant developments and various types of electronic devices are widely used in offices and homes. Examples of the electronic devices widely include a camera, a printer, a facsimile machine, a medical device, a videocassette recorder, a DVD drive, a CD drive, an electronic calculator, various types of displays, and various types of measuring instruments. Examples of electronic displays include a liquid crystal display (LCD), an organic EL display (OELD), a plasma display panel (PDP), and a field emission display (FED), which are used for a display section of each of a television receiver, a personal computer, a mobile telephone, and a personal digital assistant (PDA).

The electronic devices have been particularly lightened in weight, thinned, shortened, and reduced in size. Therefore, for some electronic devices, it is necessary to pack a large number of electronic boards into a very narrow box, to reduce a board size and a board thickness, or to provide a movable section. A flexible printed circuit (hereinafter referred to as an FPC) is generally used for wirings of an electronic board satisfying the requirements. An example of a method of connecting the electronic board with the FPC is a method using one of solder and an anisotropic conductive film (hereinafter referred to as an ACF) which is an anisotropic conductive material. In particular, in order to realize a narrow pitch of several hundred μm or less, the ACF is generally used to connect electrodes corresponding to plural wirings with one another by thermocompression bonding. Therefore, the ACF is suitably used in the case where a large number of connection terminals or a large number of electrodes are collectively simultaneously connected with one another.

In recent years, an increase in a degree of definition in boards has been advanced. An electrode connection portion in which the FPC is connected with the electronic board by thermocompression bonding is provided at a significant narrow pitch, so more reliable thermocompression bonding is required. The thermocompression bonding requires sufficient electrical connection. In view of quality control, it is important to obtain a desirable thermocompression bonding state in a connection terminal portion. Therefore, quantitative evaluation and control are necessary.

FIGS. 8 and 9 illustrate a connection method for a conventional electronic module. FIG. 8 is a schematic plane view illustrating a state before connection between an electronic parts A and an electronic parts B. FIG. 9 is a schematic plane view illustrating a state after the connection.

Extraction wirings 102 and board alignment marks 103 are formed on the board 101. The respective electrode wirings 102 serve as power supply lines, signal lines, and ground (GND) lines. For correspondence with the electrode wirings 102, ACF bonding wirings 105 whose pitch is equal to a pitch of the electrode wirings 102 and wiring width is substantially equal to a wiring width thereof, FPC alignment marks 107 of an electronic parts B, and terminals 108 are formed on an FPC 104.

Next, a process for connecting the electrode wirings 102 of the board 101 with the FPC 104 through an ACF 109 will be described. As illustrated in FIG. 8, the ACF 109 having a length required for the electrode wirings 102 of the board 101 is temporarily bonded by compression thereto.

Then, as illustrated in FIG. 9, the board alignment marks 103 of the board 101 are aligned with the FPC alignment marks 107 of the FPC 104. After the mark alignment, the board 101 and the FPC 104 are set below a head of a thermocompression bonding apparatus (not shown) and bonded to each other by compression through the ACF 109 with a pressure, a head temperature, and a compression bonding time which are required for thermocompression bonding. Thereby, the electronic module is produced.

Then, the connection between the board 101 and the FPC 104 is checked for a problem. Probes P are brought into contact with the electrode wirings 102 of the board 101 and the electrode wirings 102 located on a connection portion of the ACF (ACF connection portion). Lines are led from the terminals 108 of the FPC 104. With such a state, a resistance is measured from both the board 101 side and the FPC 104 side by a multimeter M.

However, an actual connection resistance value of only the ACF connection portion is a very small value equal to or smaller than 1Ω. Therefore, when the conventional method is used, the connection resistance value is hidden in a large resistance value, so it is very difficult to determine whether or not the connection using the ACF is adequate.

According to a structure disclosed in, for example, Japanese Patent Application Laid-Open No. 2005-209894, in order to measure a connection resistance between a display panel serving as an electronic board and the FPC with high precision and to suitably evaluate a connection state therebetween, two dummy terminals located on a board side are used. Each conductive pattern in which the two dummy terminals are connected in a square U-shape is formed. In the FPC, measurement patterns for measuring the connection resistance value are formed and land patterns are formed at the end portions of lead terminals. The board and the FPC are connected to each other by thermocompression bonding using the ACF to produce a closed circuit. When probes are brought into contact with the land patterns of the FPC, an electrical connection state obtained by thermocompression bonding can be determined using the measurement patterns. That is, it is proposed that the conductive patterns located on the board side and the measurement patterns are used to quantitatively evaluate and control whether or not a reliable thermocompression bonding is realized, based on a low resistance value.

However, the electronic module as described in Japanese Patent Application Laid-Open No. 2005-209894 has such a structure that the electrical connection state is evaluated and controlled by only a combination of the right and left dummy patterns located on the board side and the measurement patterns located on the FPC. Therefore, it is necessary to form specific dummy patterns and specific measurement patterns.

Right and left regions of the electronic module in which the measurement patterns are formed can be determined. However, a connection state of an actually used wiring cannot be determined. A pattern shape of a measurement pattern is different from a pattern shape of the actually used wiring. Therefore, even when a connection resistance of the measurement pattern is measured, the measured connection resistance may not necessarily be equal to a connection resistance of the actually used wiring. This becomes significant as a wiring pattern becomes narrower. Thus, even when faulty connection of the actually used wiring occurs, abnormality may not be detected, so the abnormality is missed by the detection.

### SUMMARY OF THE INVENTION

An object of the present invention is to provide an electronic module capable of accurately evaluating an electrical connection state of an actually used wiring without using a dummy pattern and controlling the electrical connection state, and a method of manufacturing the electronic module.

According to one aspect of the present invention, an electronic module includes: a first electronic parts including a first electrode terminal; a second electronic member including a second electrode terminal; a third electronic parts including a third electrode terminal; and a conductive connection material formed between the first electrode terminal and the second electrode terminal, for electrically connecting the first electrode terminal with the second electrode terminal, in which the second electrode terminal includes plural branch portions located in a portion other than a portion which is in contact with the conductive connection material and at least one of the plural branch portions of the second electrode terminal is electrically connected with the third electrode terminal.

According to another aspect of the present invention, a method of manufacturing an electronic module includes the steps of: preparing a first electronic parts in which a first electrode terminal is formed; preparing a second electronic parts in which a second electrode terminal including plural branch portions is formed; forming a conductive connection material between the first electrode terminal and a portion other than the branch portions of the second electrode terminal; and connecting a resistance measurement terminal with a portion other than a portion of the first electrode terminal which is in contact with the conductive connection material and the branch portions of the second electrode terminals, respectively to measure a connection resistance between the first electrode connection portion and the second electrode connection portion.

The second electrode terminal includes the plural branch portions located in the portion other than the portion which is in contact with the conductive connection material, so that a resistance value of the conductive connection material for connecting the first electrode terminal with the second electrode terminal can be measured to quantitatively determine connection reliability between the electronic parts included in the electronic module.

Further features of the present invention will become apparent from the following description of exemplary embodiments with reference to the attached drawings.

### BRIEF DESCRIPTION OF THE DRAWINGS

FIG. 1 is a schematic plan view illustrating a state before connection between a first electronic parts and a second electronic parts in Example 1 of the present invention.

FIG. 2 is a schematic plan view illustrating a state after the first electronic parts and the second electronic parts as illustrated in FIG. 1 are connected with each other.

FIG. 3 is a schematic plan view illustrating an electronic module obtained after the second electronic parts is connected with a third electronic parts in Example 1.

FIG. 4 is a schematic plan view illustrating an example of branch portions in the second electronic parts.

FIG. 5 is a schematic plan view illustrating an example of electrode wirings of the first electronic parts.

FIGS. 6A and 6B illustrate a portion of each of a first electronic parts and a second electronic parts in Example 2, in which FIG. 6A is a schematic plan view thereof and FIG. 6B is a schematic cross sectional view taken along the line 6B-6B of FIG. 6A.

FIG. 7 is a schematic cross sectional view illustrating a state after the first electronic parts and the second electronic parts which are included in the electronic module as illustrated in FIGS. 6A and 6B are connected with each other.

FIG. 8 is a schematic plan view illustrating a state before the first electronic parts and the second electronic parts which are included in an electronic module of a conventional example are connected with each other.

FIG. 9 is a schematic plan view illustrating a state after the electronic module of FIG. 8 is completed.

### DESCRIPTION OF THE EMBODIMENTS

An electronic module according to the present invention includes a first electronic parts having a first electrode terminal, a second electronic parts having a second electrode terminal, and a conductive connection material formed between the first electrode terminal and the second electrode terminal, for electrically connecting the first electrode terminal with the second electrode terminal. The second electrode terminal includes plural branch portions located in a portion other than a portion which is in contact with the conductive connection material. The electronic module further includes a third electronic parts having a third electrode terminal. At least one of the plural branch portions of the second electrode terminal is electrically connected with the third electrode terminal.

The second electrode terminal includes the plural branch portions located in the portion other than the portion which is in contact with the conductive connection material, so a connection resistance of the conductive connection material for connecting the first electronic parts with the second electronic parts can be measured. When the branched portions (branch portions) of the second electronic parts are electrically connected with the third electrode terminal of the third electronic parts, the second electrode terminal including the branch portions can be used as an actual wiring.

Hereinafter, an exemplary embodiment for embodying the present invention will be described with reference to the attached drawings.

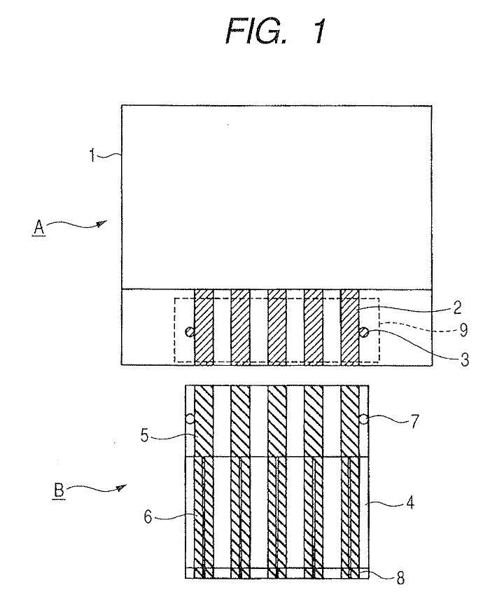

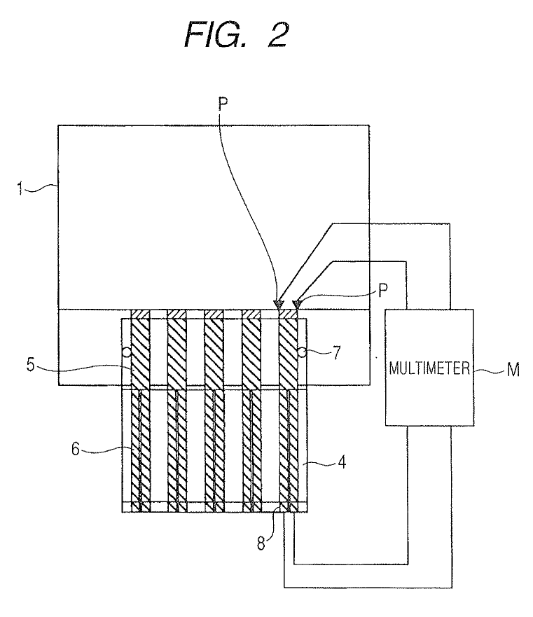

FIGS. 1 and 2 illustrate a connection method for an electronic module according to the present invention. FIG. 1 is a schematic plane view illustrating a state before connection between a first electronic parts A and a second electronic parts B. FIG. 2 is a schematic plane view illustrating a state after the connection. FIGS. 1 and 2 illustrate the first electronic parts A, the second electronic parts B, a board 1, electrode wirings 2, board alignment marks 3, an FPC 4, ACF bonding wirings 5 serving as second electrode terminals, branch portions 6 of each of the second electrode terminals, and FPC alignment marks 7, branch portion ends 8, and an ACF 9.

As illustrated in FIGS. 1 and 2, in the first electronic parts A, the electrode wirings 2 serving as the first electronic terminals and the board alignment marks 3 are formed on the board 1 serving as an electronic board. The respective electrode wirings 2 serve as power supply lines, signal lines, and ground (GND) lines, which are connected with an electronic circuit section of the board 1. The FPC 4 serving as the second electronic parts corresponding to the electrode wirings 2 includes the ACF bonding wirings 5 whose pitch is equal to a pitch of the electrode wirings 2 and wiring width is substantially equal to a wiring width thereof, serving as the second electrode terminals. Each of the ACF bonding wirings 5 is branched into the two branch portions 6 and connected therewith. The FPC 4 further includes the FPC alignment marks 7 formed therein. In this embodiment, ends of the branch portions 6 which are opposed to portions connected with the first electronic parts are assumed to be the branch portion ends 8.

As illustrated in FIG. 1, the ACF 9 having a length required for the electrode wirings 2 of the board 1 is temporarily bonded by compression thereto. Then, as illustrated in FIG. 2, the board alignment marks 3 of the board 1 are aligned with the FPC alignment marks 7 of the FPC 4. After the mark position alignment, the board 1 and the FPC 4 are set below a thermocompression bonding head (not shown) and bonded to each other by compression through the ACF 9 serving as an anisotropic conductive material with a condition including a pressure, a head temperature, and a compression bonding time which are required for thermocompression bonding.

Then, two probes (wire resistance measurement) P are brought into contact with the electrode wiring 1 of the board 1 serving as the first electronic parts. Two wirings are led from the branch portion ends 8 through the two branch potions 6 of the FPC 4. The two probes P and the two wirings are connected with a multimeter M for four-wire resistance measurement to measure a low resistance value of an ACF bonding portion.

A structure of the FPC 4 will be more specifically described. The FPC 4 includes the ACF bonding wirings 5 to be connected by thermocompression bonding, the branch portions 6, and a translucent film for holding the ACF bonding wirings 5 and the branch portions 6. The ACF bonding wirings 5 to be formed have the pitch equal to the pitch of the electrode wirings 2 of the board 1 which are located on an opposite side and the wiring width substantially equal to the wiring width thereof. The branch portions 6 are obtained by dividing each of the ACF bonding wirings 5 into substantially two. Each of the branch portions 6 have a wiring width equal to ½ of the wiring width of the ACF bonding wiring 5. A gap of approximately 20 μm is formed between the branch portions.

The wiring width of each of the branch portions 6 is not limited to ½ of the wiring width of the ACF bonding wiring 5 and thus may be ½ or less thereof or may be ½ or more thereof. At least two branch portions 6 are formed.

A sum of the wiring widths of the two branch portions 6 is desirably equal to or larger than the wiring width of the ACF bonding wiring 5 in the case where the branch portions 6 are used for a wiring for supplying a large current. When a supplied current is small or when the branch portions 6 are used for a signal line, the sum of the wiring widths of the branch portions 6 may be smaller than the wiring width of the ACF bonding wiring 5. One of the two branch portions 6 may be a thick wiring and the other thereof may be a thin wiring. When one of the wirings is used for only resistance measurement, the thin wiring can be used as a wiring for resistance measurement and the thick wiring can be used as a wiring for both resistance measurement and driving.

The gap formed between the branch portions may be any gap in which adjacent branch portions are not short-circuited. When the branch portions are provided as two wirings for four-wire resistance measurement using a four-wire resistance measurement instrument, the branch portions may be formed in any shape. When the two wirings can be led, two or more branch portions may be formed.

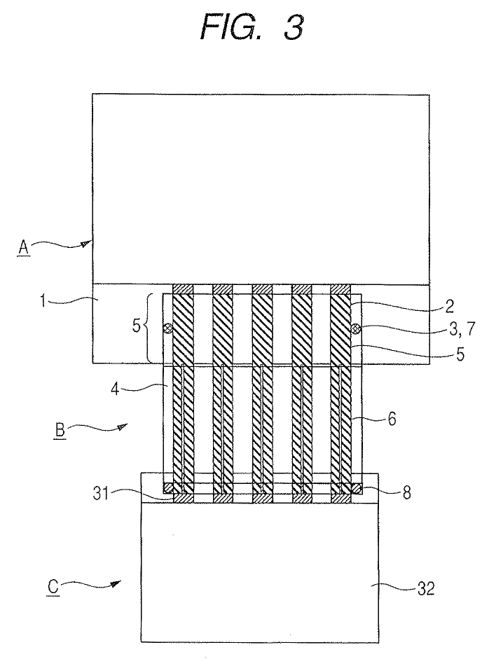

Then, the branch portion ends 8 of the FPC 4 serving as the second electronic parts are connected with a third electronic parts C as illustrated in FIG. 3. FIG. 3 is a schematic plan view illustrating the electronic module according to the present invention, that is, a state in which the first electronic parts A, the second electronic parts B, and the third electronic parts C are electrically connected with one another. FIG. 3 illustrates third electrode terminals 31 and a controller 32.

When the third electronic parts is an electronic parts connected with the second electronic parts, the third electronic parts is not particularly limited. However, for example, as illustrated in FIG. 3, the third electronic parts includes the controller 32 for generating control signals for controlling the first electronic parts. The branch portions 8 of the second electronic parts are desirably formed corresponding to a shape of the third electronic parts to be connected next. For example, when the third electronic parts is a connector, a shape for connector may be employed. When ACF bonding is to be performed, a shape for ACF may be employed. When soldering is to be performed, a shape for soldering may be employed. In this embodiment, the second electrode terminals of the second electronic parts are bonded with the third electrode terminals of the third electronic parts through the ACF. Each of the third electrode terminals is provided in common to plural branched portions (branch portions) of each of the second electrode terminals and electrically connected therewith.

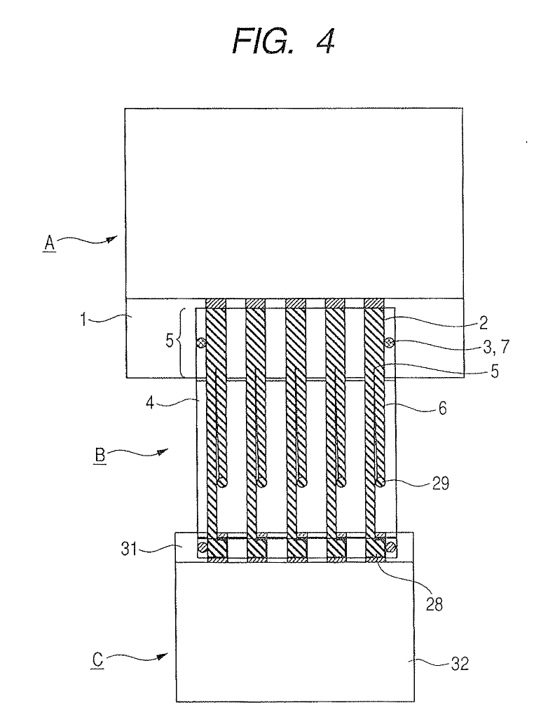

In this embodiment, description has been made referring to an example in which both the two branch portion ends 8 of the second electronic parts are connected with the third electrode terminal. However, according to the present invention, all the plural branch portion ends may not necessarily be connected with the third electrode terminal. For example, as illustrated in FIG. 4, the following structure may be employed. A part (one branch portion end 8) of the plural branch portion ends 28 is connected with the third electrode terminal and the other branch portion ends 29 are not connected with the third electrode terminal and thus used only as wirings for connection resistance measurement. In FIG. 4, the same symbol in FIG. 3 shows the same member as that in FIG. 3.

In this embodiment, the FPC is used as the second electronic parts. However, the present invention is not limited to the FPC. Therefore, any board having wirings connected with the electronic board serving as the first electronic parts, such as wirings for TAB or wirings formed on a glass epoxy thin board, may be employed.

In this embodiment, the electronic board in which only one group including the plural electrode wirings is provided on one side of the board is described. However, the electrode wirings may be formed on each of four sides of the board or plural groups each including electrode wirings may be provided on one side thereof. Although the electronic board including the plural electrode wirings is described, a single electrode wiring may be used.

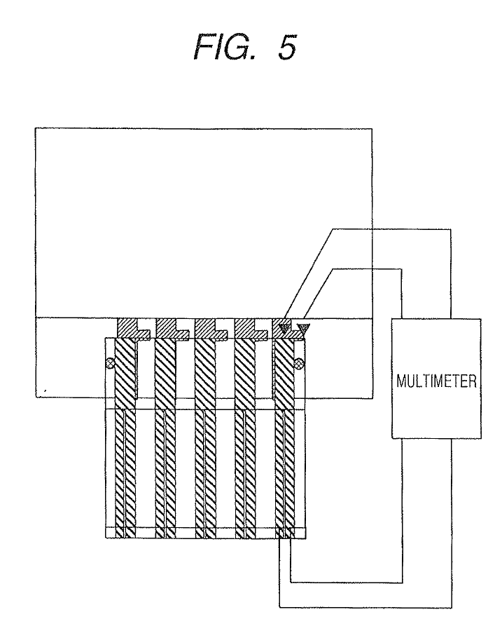

When there is no problem in using the electronic board serving as the first electronic parts, as illustrated in FIG. 5, an electrode wiring portion other than the ACF connection portion, of each of the electrode wirings and a wiring portion which extends therefrom may be formed as two or more branch wiring portions. When the electrode wiring located on the board 1 side is thin, it is desirable to branch the electrode wiring located on the board 1 side or lead only one electrode wiring to a different region. In this case, the probes are not brought into contact with portions immediately above the ACF connection portion of the electrode wiring. Two wirings are desirably led from any positions on two or more division wirings of the electronic board by any method to be able to measure a resistance. In such measurement, when a four-wire resistance measurement jig to be used is produced instead of the probes, the resistance can be measured more easily.

Examples of the electronic module include an FPC connected with a semiconductor integrated circuit board serving as the electronic board and an FPC connected with a display panel serving as the electronic board. Examples of an electronic devices containing the electronic module includes a camera, a printer, a facsimile machine, a medical device, a videocassette recorder, a DVD drive, a CD drive, an electronic calculator, various types of displays, and various types of measuring instruments. Examples of the displays include a liquid crystal display (LCD), an organic EL display (OELD), a plasma display panel (PDP), and a field emission display (FED), which are used for a display section of each of a television receiver, a personal computer, a mobile telephone, and a personal digital assistant (PDA). In particular, when an organic EL display operated by current driving is manufactured, light emission is significantly influenced by a resistance of the ACF connection portion. Therefore, an effect that a light emission intensity is made uniform is large in the case where the structure of the electronic module according to the present invention is employed. When the organic EL display is manufactured, the first electronic parts in this embodiment serves as an organic EL panel (organic electroluminescence panel).

Hereinafter, the electronic module according to the present invention and a method of manufacturing the electronic module will be described in a manufacturing order. However, the present invention is not limited to the following structures and the following manufacturing methods.

### EXAMPLE 1

FIGS. 1 and 2 illustrate the wiring structure of the electrode connection portion between the first electronic parts and the second electronic parts in Example 1. The board 1 includes the electrode wirings 2 and the board alignment marks 3. The FPC 4 includes the ACF bonding wirings 5, the two branch portions 6 from each of the ACF bonding wirings 5, and the FPC alignment marks 7. The electrode wirings 2 of the board 1 are ACF-connected with the ACF bonding wirings 5 of the FPC 4 through the ACF 9.

Hereinafter, the method of manufacturing the electronic module will be described.

(Condition Determination and Reliability Evaluation)

A heater head temperature, a compression bonding pressure, and a compression bonding time, each of which were an ACF connection condition, were changed. The first electronic parts was connected with the second electronic parts in each changed condition. Probes were brought into contact with portions immediately above the FPC, of an electrode wiring of the board of each electronic module which was bonded to the FPC. Two wirings were led from the branch portions of the FPC. The two probes and the two wirings were connected with the multimeter for four-wire resistance measurement to measure a low resistance value of the ACF connection portion. Such operation was performed for each of the electrode wirings in each condition to measure an initial resistance value.

The first electronic parts and the second electronic parts which were connected with each other in each changed condition were placed in a contrast temperature bath and a reliability test was performed under the condition of a high temperature and a high humidity for 1,000 hours. After a lapse of 1,000 hours, the first electronic parts and the second electronic parts which were connected with each other and placed in the bath were taken out. Then, as in the initial case, the two wirings were led from the branch portions of the FPC. The two probes and the two wirings were connected with the multimeter for four-wire resistance measurement to measure a low resistance value of only the ACF connection portion. Such measurement was performed in each condition.

Members having highest reliability were determined based on the initial resistance values and a result obtained by measurement on a change in resistance value during 1,000 hours. A heater head temperature, a compression bonding pressure, and a compression bonding time with respect to the determined members were set as manufacturing conditions.

In this example, the test is performed at a high temperature and a high humidity for 1,000 hours. However, a heat cycle test which can be carried out in a relatively short time may be performed as the reliability test to determine the conditions.

(Connection between First Electronic Parts and Second Electronic Parts)

The first electronic parts in which the electrode wirings (first electrode terminals) were formed on the board and the second electronic parts in which the ACF bonding wirings (second electrode terminals) had been formed were prepared. The ACF connection was made based on the manufacturing conditions obtained by the condition determination to connect the first electronic parts with the second electronic parts.

The ACF 9 having a length required for the electrode wirings 2 of the board 1 was temporarily bonded by compression thereto. Then, the board alignment marks 3 of the board 1 were aligned with the FPC alignment marks 7 of the FPC 4. After the mark position alignment, the board 1 and the FPC 4 were set below a thermocompression bonding head (not shown) and bonded to each other by compression through the ACF 9 with the manufacturing conditions including the heater head temperature, the compression bonding pressure, and the compression bonding time, with the result that the first electronic parts was connected with the second electronic parts.

(Check of ACF Connection Portion)

One of groups each including the first electronic parts and the second electronic parts which had been compression-bonded by the above-mentioned process was extracted and the two probes P were brought into contact with portions immediately above the FPC 4 of the electrode wiring 2 of the board 1 which was bonded to the FPC 4. The two wirings were led from the branch portion ends 8 of the branch portions 6 of the FPC 4. The two probes and the two wirings were connected with the multimeter M for four-wire resistance measurement to measure a low resistance value of only the ACF connection portion. A resistance value of each of the electrode wirings of the electronic module was measured in the same manner. In such measurement, when a specific four-wire resistance measurement jig is used instead of the probes, the resistance can be more easily measured in a short time.

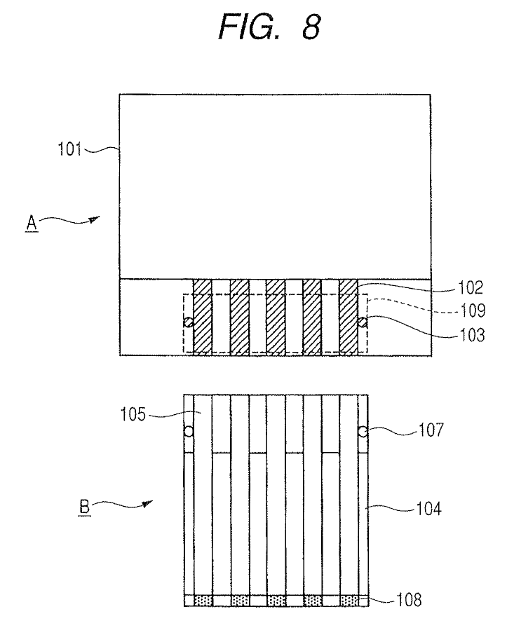

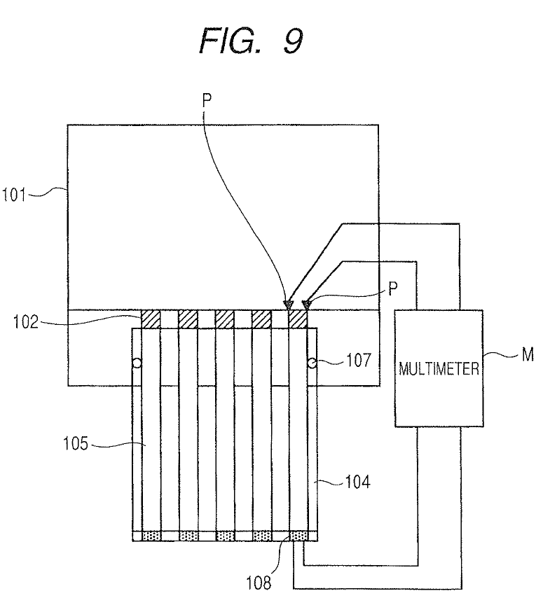

For comparison, the conventional first electronic parts and the second electronic parts as illustrated in FIGS. 8 and 9 were manufactured with the same conditions as those in Example 1.

For each group including the first electronic parts and the second electronic parts which were connected with each other, the two probes were brought into contact with the portions immediately above the FPC, of the electrode wiring of the board which was bonded to the FPC. The two wirings were led from end terminals of the FPC. The two probes and the two wirings were connected with the multimeter for four-wire resistance measurement to perform resistance value measurement. A resistance value of each of the electrode wirings of each member was measured.

(Measurement Value Comparison)

An average value of resistance measurement values in the case of Example 1 was 0.37Ω. An average value of resistance measurement values in the comparison example was 4.5Ω. Therefore, there was a large difference in the resistance values. This reason is as follows. In the conventional case, a large resistance value is exhibited because a resistance value of the entire electronic parts is also included thereto. On the other hand, in the case of Example 1, the resistance value of only the ACF connection portion can be substantially measured.

As described above, in the conventional case, the resistance value of the connection portion was hidden in the large resistance value of the entire electronic parts, so it was difficult to detect a fault in the connection portion. In contrast, when the low resistance value can be measured as in the case of Example 1, whether or not the manufacturing conditions of the electronic module have abnormality or whether or not partial fault occurs can be instantaneously determined by a sampling inspection. Therefore, accurate inspection and evaluation can be performed.

In this example, the sampling inspection of manufacturing lots was performed. However, a 100% inspection may be performed instead of the sampling inspection.

The condition determination and the reliability test can be performed using products, so it is unnecessary to manufacture specific electronic parts for condition determination and reliability test and a manufacturing cost is reduced.

(Connection between Second Electronic Parts and Third Electronic Parts)

The third electronic parts in which the third electrode terminals had been formed was prepared. The third electronic parts was connected with the first electronic parts and the second electronic parts which had been connected with each other through the ACF. In this example, the ACF connection was performed as in the case of the connection between the first electronic parts and the second electronic parts. The ACF having a length required for the third electrode terminals 31 of the controller 32 was temporarily bonded by compression thereto. Then, board alignment marks of the controller 32 were aligned with the FPC alignment marks of the FPC 4. After the mark position alignment, the controller 32 and the FPC 4 were set below the thermocompression bonding head (not shown) and bonded to each other by compression through the ACF with the manufacturing conditions including the heater head temperature, the compression bonding pressure, and the compression bonding time, with the result that the electronic module is produced.

### EXAMPLE 2

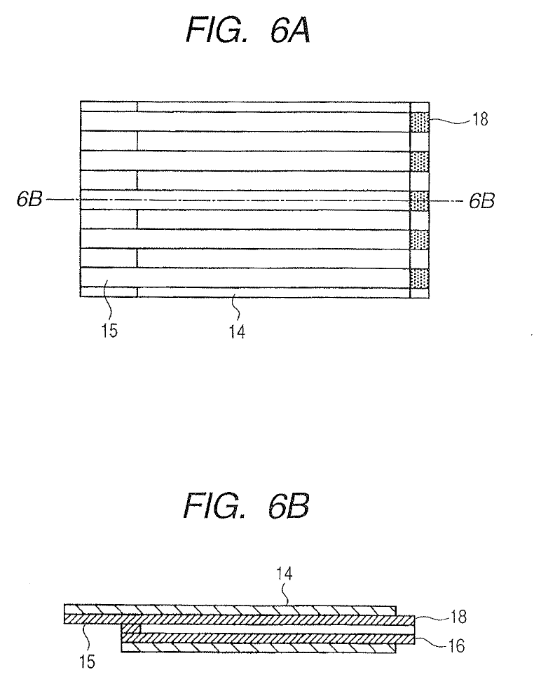

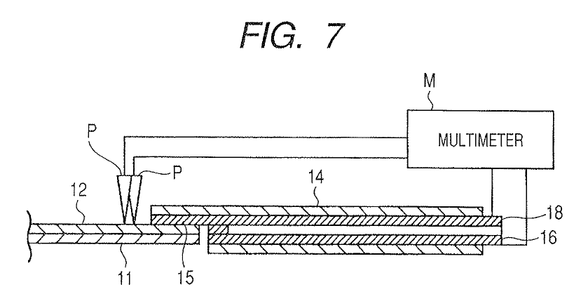

FIGS. 6A, 6B, and 7 illustrate Example 2. A board (electronic board) 11 serving as the first electronic parts includes electrode wirings 12 serving as the first electrode terminals. An FPC 14 serving as the second electronic parts includes ACF bonding wirings 15 serving as the second electrode terminals, and a lower electrode 16 and an upper electrode 18 which are branches from each of the ACF bonding wirings 15.

A point in which this electronic module is different from the electronic module according to Example 1 will be described. FIG. 6A is a plan view illustrating the FPC 14 and FIG. 6B is a cross sectional view taken along the line 6B-6B of FIG. 6A. As illustrated in FIG. 6B, the FPC 14 includes the lower electrode 16 which branches from each of the ACF bonding wirings 15, extends in a thickness direction, and is located on the lower side. The lower electrode 16 had a width substantially equal to a width of each of the ACF bonding wirings 15. Therefore, the FPC 14 in this example had a two-layer wiring structure in which each wiring was divided into two.

(Condition Determination and Reliability Evaluation)

As in the case of Example 1, in order to determine the manufacturing conditions, the first electronic parts was connected with the second electronic parts. As illustrated in FIG. 7, the two probes P were brought into contact with portions immediately above the FPC 14, of the electrode wiring 12 of the board 11 which had been bonded to the FPC 14. Two wirings were led from the lower electrode 16 and the upper electrode 18 which were two-layer wirings of the FPC 14. The two probes P and the two wirings were connected with the multimeter M for four-wire resistance measurement to measure a low resistance value of only the ACF connection portion. By using such a method, an initial low resistance value of the connection portion between the first electronic parts and the second electronic parts was measured, and a resistance value thereof after a high-temperature high-humidity test was performed for 1,000 hours was measured. Then, the resistance values were compared with each other. Therefore, when the condition determination and the reliability test were performed as in the case of Example 1, an optimum condition could be found.

As a result obtained by measurement after the test, a heater head temperature, a compression bonding pressure, and a compression bonding time with respect to members having highest reliability were set as the manufacturing conditions.

(Connection Between First Electronic Parts and Second Electronic Parts)

An ACF (not shown) having a length required for the electrode wirings 12 of the board 11 was temporarily bonded by compression thereto. Then, board alignment marks (not shown) of the board 11 were aligned with FPC alignment marks (not shown) of the FPC 14. After the mark position alignment, the board 11 and the FPC 14 were set below the thermocompression bonding head (not shown) and bonded to each other by compression through the ACF with the manufacturing conditions including the heater head temperature, the compression bonding pressure, and the compression bonding time, with the result that the first electronic parts was connected with the second electronic parts.

(Check of ACF Connection Portion)

One of groups each including the first electronic parts and the second electronic parts which had been compression-bonded by the above-mentioned process was extracted and the two probes P were brought into contact with portions immediately above the FPC 14, of the electrode wiring 12 of the board 11 which was bonded to the FPC 14. Two wirings were led from the lower electrode 16 and the upper electrode 18 which were the two-layer wirings of the FPC 14. The two probes P and the two wirings were connected with the multimeter M for four-wire resistance measurement to measure a low resistance value of only the ACF connection portion. A resistance value of each of the electrode wirings of the electronic module was measured by the above-mentioned operation. As a result, it could be determined that there was no problem on the bonding states of all the wirings. In such four-wire resistance measurement, when a specific four-wire resistance measurement jig is produced instead of the probes, the resistance can be more easily measured in a short time.

The FPC 14 includes the ACF bonding wirings 15 to be connected by thermocompression bonding, the lower electrodes 16, the upper electrodes 18, and a film for holding the ACF bonding wirings 5, the lower electrodes 16, and the upper electrodes 18. The upper electrodes 18 to be formed have a pitch equal to a pitch of the electrode wirings 12 of the board 11 which are located on an opposite side and a wiring width substantially equal to a wiring width thereof. The lower electrodes 16 serving as lower branch wirings have a pitch equal to a pitch of the ACF bonding wirings 15 and a width substantially equal to a width thereof. A current may be led from one of the lower electrode 16 and the upper electrode 18. In the case of a wiring for supplying a large current, the current may be supplied from two upper and lower wirings.

When a supplied current is small or when the lower electrode 16 and the upper electrode 18 are used for a signal line, the width of each thereof may be smaller than the width of the ACF bonding wiring 15. One of the lower electrode 16 and the upper electrode 18 which are lower and upper wirings may be a thick wiring and the other thereof may be a thin wiring. When two wirings are led for four-wire resistance measurement, branch portions each including two or more wiring layers may be formed.

In this example, the sampling inspection of manufacturing lots was performed. However, a 100% inspection may be performed instead of the sampling inspection.

The condition determination and the reliability test can be performed using products, so it is unnecessary to manufacture specific electronic parts for condition determination and reliability test and a manufacturing cost is reduced.

In this example, the wirings can be led from the same positions in a longitudinal direction of the terminal portion. Therefore, for example, the contact with a connector can be made at any of the positions. The contact can be made with each of the upper and lower wirings, so two kinds of connectors can be used. Even in the case of the ACF connection, the bonding can be made with any of the upper and lower wirings, so a leading manner which is more suitable for the electronic module can be employed.

(Connection Between Second Electronic Parts and Third Electronic Parts)

The third electronic parts was further connected with the first electronic parts and the second electronic parts which had been connected with each other through the ACF. In this example, the ACF connection was performed as in the case of the connection between the first electronic parts and the second electronic parts. The ACF having a length required for the third electrode terminals of the controller was temporarily bonded by compression thereto. Then, the board alignment marks of the controller were aligned with the FPC alignment marks of the FPC. After the mark position alignment, the controller and the FPC were set below the thermocompression bonding head (not shown) and bonded to each other by compression through the ACF with the manufacturing conditions including the heater head temperature, the compression bonding pressure, and the compression bonding time, with the result that the electronic module was produced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2006-228754, filed Aug. 25, 2006, and 2007-202724, filed Aug. 3, 2007, which are hereby incorporated by reference herein in their entirety.

What is claimed is:

1. An electronic module comprising:
a first electronic parts including a first electrode terminal;
a second electronic parts including a second electrode terminal;
a third electronic parts including a third electrode terminal; and
a conductive connection material formed between the first electrode terminal and the second electrode terminal, for electrically connecting the first electrode terminal with the second electrode terminal,
wherein the second electrode terminal includes plural branch portions located in a portion other than a portion which is in contact with the conductive connection material and at least one of the plural branch portions of the second electrode terminal is electrically connected with the third electrode terminal.

2. The electronic module according to claim 1, wherein the third electrode terminal is provided in common to the plural branch portions of the second electrode terminal and electrically connected therewith.

3. The electronic module according to claim 1, wherein:
the first electronic parts includes plural first electrode terminals;
the second electronic parts includes plural second electrode terminals;
the third electronic parts includes plural third electrode terminals; and
each of the second electrode terminals comprises plural branch portions located in the portion other than the portion which is in contact with the conductive connection material.

4. The electronic module according to claim 1, wherein the first electrode terminal comprises plural branch portions located in a portion other than a portion which is in contact with the conductive connection material.

5. The electronic module according to claim 1, wherein the conductive connection material comprises an anisotropic conductive material.

6. The electronic module according to claim 1, wherein the second electrode terminal is branched in a thickness direction.

7. The electronic module according to claim 1, wherein the first electronic parts comprises a display panel.

8. The electronic module according to claim 1, wherein the first electronic parts comprises an organic electroluminescence panel.

9. The electronic module according to claim 1, wherein the first electronic parts comprises a semiconductor integrated circuit board.

10. The electronic module according to claim 1, wherein the second electronic parts comprises a flexible printed circuit.

11. A method of manufacturing an electronic module, comprising the steps of:
preparing a first electronic parts in which a first electrode terminal is formed;
preparing a second electronic parts in which a second electrode terminal including plural branch portions is formed;
forming a conductive connection material between the first electrode terminal and a portion other than the branch portions of the second electrode terminal; and
connecting a resistance measurement terminal with a portion other than a portion of the first electrode terminal which is in contact with the conductive connection material and the branch portions of the second electrode terminals, respectively to measure a connection resistance between the first electrode connection portion and the second electrode connection portion.

12. The method according to claim 11, further comprising the steps of:
preparing a third electronic parts in which a third electrode terminal is formed; and
electrically connecting at least one of the plural branch portions of the second electrode terminal with the third electrode terminal after the measuring of the connection resistance.

13. The method according to claim 12, wherein the electrically connecting of the at least one of the plural branch portions of the second electrode terminal with the third electrode terminal comprises a step of electrically connecting the plural branch portions of the second electrode terminal with the third electrode terminal provided in common thereto.
